(19) United States
(12) Patent Application Publication
(10) Pub. No.: US 2007/0262295 A1
(43) Pub. Date: Nov. 15, 2007

(54) A METHOD FOR MANIPULATION OF OXYGEN WITHIN SEMICONDUCTOR MATERIALS

(75) Inventor: Darwin G. Enicks, Colorado Springs, CO (US)

Correspondence Address: SCHNECK & SCHNECK, P.O. BOX 2-E, SAN JOSE, CA, 95109-0005, US

(73) Assignee: ATMEL CORPORATION, San Jose, CA (US)

(21) Appl. No.: 11/421,161

(22) Filed: May 31, 2006

Related U.S. Application Data
(60) Provisional application No. 60/747,080, filed on May 11, 2006.

(51) Int. Cl. H01L 31/00; H01L 21/265; H01L 29/06

(52) U.S. Cl. 257/19; 438/518

(57) ABSTRACT

Methods and electronic devices fabricated by those methods are disclosed where the method allows controlled movement of oxygen during fabrication of electronic and photonic devices, facilitated by a technique of oxygen updiffusion (OUD). The method includes fabrication of a compound semiconductor film, doped with either carbon or boron, over a substrate and incorporating a quantity of oxygen into either the substrate or an adjacent film layer. One or more anneal steps may be used as a partial control mechanism, along with dopant types, concentrations, and profiles, to control movement of the oxygen from the semiconductor substrate or adjacent films into the compound semiconductor film.

### CROSS-REFERENCE TO RELATED APPLICATION

This application claims priority from U.S. provisional application No. 60/747,080, filed May 11, 2006.

### TECHNICAL FIELD

The invention generally relates to methods of fabricating integrated circuits (ICs). More specifically, the invention is a method of fabricating and manipulating oxygen into an electronic device such as a SiGe heterojunction bipolar transistor (HBT).

### BACKGROUND AND RELATED ART

The SiGe HBT has significant advantages over a silicon (Si) bipolar junction transistor (BJT) in characteristics such as gain, frequency response, and noise parameters. Further, the SiGe HBT is able to integrate with CMOS devices at relatively low cost. Cutoff frequencies, Fₜ, of SiGe HBT devices have been reported to exceed 300 GHz, which compares favorably with gallium-arsenide (GaAs) devices. However, GaAs devices are relatively high in cost and cannot achieve a level of integration that can be achieved with BiCMOS devices. A silicon-compatible SiGe HBT provides a low cost, high speed, low power solution that is quickly replacing other compound semiconductor devices.

Advantages of SiGe are realized partially due to an enhanced capability for bandgap engineering due to an addition of Ge to a Si lattice. For instance, an energy band offset at the Si—SiGe heterojunction of the HBT results in increased current densities and lower base current for a given base-emitter bias, equating to higher gains. Also, a lower resistivity is possible with addition of Ge to the Si lattice. The higher current densities and lower base resistance values allow improved unity gain cutoff frequencies and maximum oscillation frequencies than comparable silicon BJTs and are comparable to other compound devices such as GaAs. However, the emitter collector breakdown voltage (especially BVCEO) is inversely proportional to the current gain (β). The structural and process changes required to enhance cutoff frequencies and reduce power lead to increasingly higher current gains and hence decreasingly lower collector-emitter breakdown voltages.

Elevated Ge fractions result in an increase in base recombination current and a reduction in current gain for a given layer thickness and doping level. The base recombination current increase/current gain reduction effect has been confirmed experimentally to extend beyond 30% Ge. References on defect formation is pseudomorphic SiGe with high Ge content suggest the effect will continue to increase for Ge fractions well above 40% (i.e., Kasper et al., “Properties of Silicon Germanium and SiGe:Carbon”, INSPEC, 2000). Therefore, a compromise of increasing Ge fraction high enough to reduce current gain in high-speed devices provides a way to compensate for an inevitable increase in gain and degradation of BVCEO as base-widths continue to shrink.

However, there is a limit to how much Ge can be added to the Si lattice before excess strain relaxation and gross crystalline defects occur. A critical thickness, h_{c}, of a SiGe layer that is lattice matched to underlying silicon is primarily a function of: (1) percentage of Ge employed; (2) SiGe film thickness; (3) a thickness of a cap layer; (4) temperature of HBT film-stack processing; and (5) temperature of thermal anneals following a SiGe deposition. Above the critical thickness, h_{c}, the SiGe film is in a metastable and/or unstable region which implies it will relax readily with a large enough application of thermal energy. Therefore, a degree of metastability is largely a function of percentage of Ge, SiGe layer thickness, cap layer thickness, and process induced strain due to thermal energy. Construction of a SiGe base of a conventional SiGe HBT described to date is that of a stable pseudomorphic or lattice-matched layer. Contemporaneous state-of-the-art procedures include growing stable, strained, or lattice-matched alloys of SiGe with carbon to prevent spreading of a boron concentration-profile in the base region.

Metastable film growth is typically avoided due to the fact that relaaxation results in lattice imperfections. These imperfections result in recombination centers; hence, a reduction in minority carrier lifetime, τ_{BO}, and an increase in base recombination current, I_{RB}, occurs. If not controlled, the resultant poor crystal quality due to lattice imperfections will degrade device performance. Bridging defects will also lead to excessive leakage current along with extremely low current gain. The film will also be very sensitive to process induced thermal stresses and therefore will not be manufacturable. Therefore, to avoid this type of degradation, the HBT designs to date result in a device with a base region that is in the stable region of film growth which equates to a SiGe thickness that is equal to or below the critical thickness, h_{c}.

It is known that oxygen will reduce dislocation velocities of metastable films by an order of magnitude. Therefore oxygen incorporation into the crystalline lattice is beneficial in delaying an onset of undesirable relaxation effects in high-percentage Ge films (see D. C. Houghton, “Strain relaxation kinetics in Si₁₋ₓGeₓ/Si heterostructures,” J. Appl. Phys., 70 (4), p. 2142 (Aug. 15, 1991)). It is also known that oxygen will reduce boron diffusion much the same as carbon (See D. Knoll et al., “Influence of the Oxygen Content in SiGe on Parameters of Si/SiGe Heterojunction Bipolar Transistors,” Journal of Electronic Materials, Vol. 27, No. 9 (1998). Therefore, there are multiple benefits with controlled oxygen incorporation. In fact, the intentional addition of oxygen to the SiGe lattice represents a radical departure from contemporary mainstream technologies and may have significant importance for the near future as will be discussed in detail, infra. However, contemporary fabrication techniques are unable to precisely control oxygen placement into film layers.

Further, carbon incorporated into SiGe films, in addition to reducing boron diffusion, will assist in compensating compressive strain in pseudomorphic SiGe by reducing an average lattice parameter relative to the Si. However, carbon also outdiffuses rapidly during thermal anneals, which follow the growth of strained silicon germanium carbon films.

To achieve even greater energy band offsets, ΔEv, it is therefore necessary to integrate even more Ge. However, an upper limit of the metastable regime places a constraint on SiGe processing and device design as partially detailed supra. As the upper limit is approached, crystalline defect propagation is greatly enhanced with an accelerated relaxation of the strained SiGe film.

Oxygen is frequently utilized in the semiconductor and allied industries only for particular fabrication procedures. Commonly, oxygen is used for procedures such as thermally-grown or deposited oxides of silicon for insulation and gate dielectric layers, and formation of oxygen precipitates. Oxygen precipitates, also called internal gettering, are used in Czochralski (CZ) grown silicon substrates for purposes of reducing crystalline defects in active silicon regions near a surface of the substrate (i.e., formation of a denuded zone).

However, oxygen is frequently considered an unwanted contaminant in various electronic and photonic fabrication processes. Oxygen contaminates thermal and plasma processes in etch, thin film deposition, and silicon (Si), silicon germanium (SiGe), and germanium (Ge) epitaxy. However, an ability to control movement of oxygen within layers of Si, SiGe, and Ge is of significant benefit to advanced semiconductor processing. It would be desirable to control movement of oxygen during manufacturing of electronic and photonic devices, facilitated by a technique of oxygen updiffusion (OUD).

### SUMMARY OF THE INVENTION

Embodiments of the present invention describe methods and electronic devices fabricated by those methods where the method allows controlled movement of oxygen during fabrication of electronic and photonic devices, facilitated by a technique of oxygen updiffusion (OUD).

In one embodiment, the present invention is a method for fabricating a compound semiconductor film where the semiconductor substrate and forming a compound semiconductor film over a first surface of the substrate. The compound semiconductor film contains a dopant element. The semiconductor substrate and the compound semiconductor film are annealed and a movement of the oxygen from the semiconductor substrate into the compound semiconductor film of the oxygen is controlled.

In another embodiment, the present invention is a method for fabricating a compound semiconductor film where the method includes forming a compound semiconductor film over a first surface of a substrate. The compound semiconductor film contains a dopant element. A semiconductor cap layer is formed over the compound semiconductor film and a quantity of oxygen is incorporated into the semiconductor cap layer. The compound semiconductor film, and the semiconductor cap layer are annealed and a movement of the oxygen from the semiconductor cap layer into the compound semiconductor film is controlled.

In another embodiment, the present invention is a method for fabricating a compound semiconductor film where the method includes forming a compound semiconductor film over a first portion of a first surface of the substrate. The compound semiconductor film contains a dopant element. At least one additional semiconductor layer is formed over a second portion of the substrate and next to the compound semiconductor film. A quantity of oxygen is incorporated into the at least one additional semiconductor layer. The substrate, the compound semiconductor film, and the at least one additional semiconductor layer are annealed and a movement of the oxygen from the at least one additional semiconductor layer into the compound semiconductor film is controlled.

In another embodiment, the present invention is an electronic device including a substrate, a silicon germanium film disposed over a first surface of the substrate, a dopant containing carbon incorporated into the silicon germanium film, and a quantity of oxygen updiffused into the silicon germanium film.

In another embodiment, the present invention is an electronic device including a substrate, a silicon germanium film disposed over a first surface of the substrate, a dopant containing boron incorporated into the silicon germanium film, and a quantity of oxygen updiffused into the silicon germanium film.

In another embodiment, the present invention is a method for fabricating a heterojunction bipolar transistor where the method includes incorporating a quantity of oxygen into a semiconductor substrate, forming a silicon germanium film over a first surface of the substrate, and doping the silicon germanium semiconductor film with a strain-compensating atomic species. The semiconductor substrate and the silicon germanium semiconductor film are annealed and a movement of the oxygen from the semiconductor substrate into the silicon germanium film is controlled.

In another embodiment, the present invention is a method for fabricating a heterojunction bipolar transistor where the method includes forming a silicon germanium film over at least a first portion of the first surface of the substrate, doping the silicon germanium semiconductor film with a strain-compensating atomic species, forming at least one additional semiconductor layer adjacent to the silicon germanium film, and incorporating a quantity of oxygen into the at least one additional semiconductor layer. The silicon germanium film, and the at least one additional semiconductor layer are annealed and a movement of the oxygen from the at least one additional semiconductor layer into the silicon germanium film is controlled.

### BRIEF DESCRIPTION OF THE DRAWINGS

FIG. 1 indicates minority carrier lifetime (τ_{B0}) as a function of oxygen concentration in a semiconductor.

FIG. 2 indicates recombination current density as a function of minority carrier lifetime (τ_{BO}).

FIG. 3 indicates common emitter gain as a function of minority carrier lifetime (τ_{BO}).

FIG. 4 indicates collector-to-emitter breakdown voltage (BVCEO) as a function of minority carrier lifetime (τ_{BO}).

FIG. 5 indicates concentration of oxygen from results from secondary ion mass spectrometry (SIMS) as a function of depth into a silicon substrate.

FIG. 6 indicates oxygen profiles near a silicon substrate surface for various prebake temperatures.

FIG. 7 indicates atomic concentration of various elements near the surface of a silicon substrate.

FIG. 8 indicates atomic concentration of various elements in an as-grown silicon germanium (SiGe) film prior to any thermal treatment.

FIG. 9 indicates oxygen updiffusion into a strained semiconductor as measured by SIMS.

FIG. 10 indicates oxygen pileup in SiGe as measured by SIMS.

FIG. 11 indicates peak oxygen levels as a function of prebake temperature.

FIG. 12A indicates peak oxygen as a function of carbon dose after anneal.

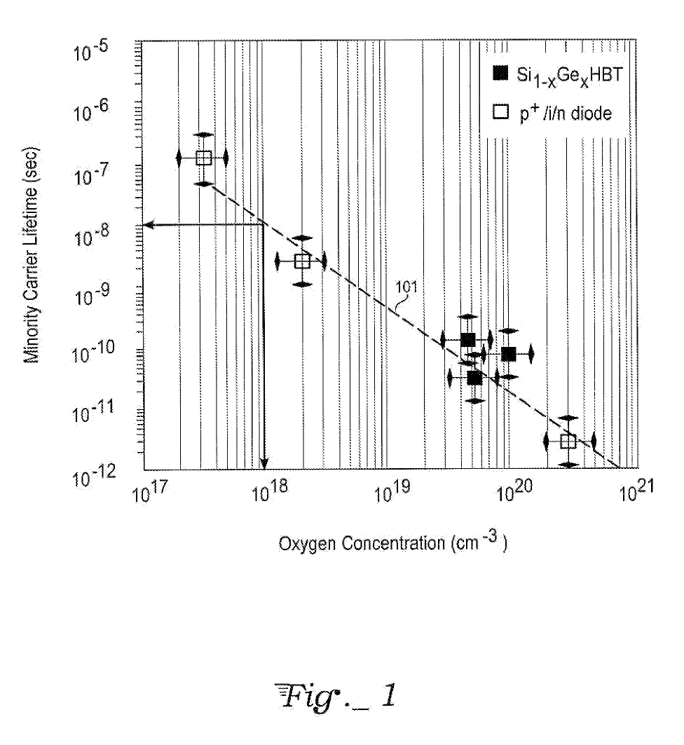

FIG. 1B indicates peak oxygen due to OUD as a function of post film growth anneal temperatures.

FIG. 13A is a semiconductor film stack formed over a silicon substrate.

FIG. 13B is the semiconductor film stack of FIG. 13A showing updiffusion of oxygen.

FIG. 14 indicates updiffusion of oxygen concentration after an anneal step.

FIG. 15 indicates formation of an oxygen depleted region beneath a Si, SiGe, or Ge layer that is doped with boron and/or carbon.

FIG. 16A illustrates lateral movement of oxygen may occur from adjoining regions.

FIG. 16B illustrates a lateral movement of updiffused oxygen from adjoining regions.

FIG. 17A indicates oxygen added to a semiconductor substrate.

FIG. 17B indicates additional semiconductor layers formed above the semiconductor substrate of FIG. 17A.

FIG. 17C indicates one type of updiffusion of oxygen from the substrate of FIG. 17B.

FIG. 17D indicates another type of updiffusion of oxygen from the substrate of FIG. 17B.

FIG. 17E indicates another type of updiffusion of oxygen from the substrate of FIG. 17B.

### DETAILED DESCRIPTION

Embodiments of the present invention describe methods to control movement of oxygen during manufacturing of electronic and photonic devices, facilitated by a technique of oxygen updiffusion (OUD). OUD allows enhanced control of oxygen in microelectronics, photonics, SOI, and nanotechnologies.

Generally, OUD refers to both the updiffusion of oxygen and various techniques and methodologies, described herein, for precise and repeatable placement of oxygen. For example, OUD can be used for precise relocation of oxygen from point A to point B and thus allows for precise control of oxygen movement within a film, from a substrate to a film, or from one film to another. In this context, films include nanolayers and nanocrystals. Commensurate with the movement of oxygen, OUD techniques further allow control and formation of oxygen-rich regions and oxygen-depleted regions.

An Overview of OUD

Although general and specific embodiments will be described in detail herein, some general principles are common to the various embodiments and equivalents thereof.

(1) OUD is enhanced by the presence of either boron, carbon, and/or fluorine in strained, metastable, and unstable or relaxed silicon germanium. As presented herein, the OUD effect still occurs even with reductions in germanium.

(2) Oxygen can diffuse a considerable distance (e.g., greater than one micrometer (1 μm)) from an underlying substrate and/or surrounding layers into a strained SiGe layer. The oxygen diffusion is closely aligned to the carbon and/or boron profiles.

(3) An oxygen pileup in strained SiGe has been noted to reach concentrations that are more than 100-times greater that a background concentration of oxygen in any adjacent layer (e.g., in an underlying Si substrate or adjacent semiconductor layer). OUD thus provides a method of moving oxygen from one region to another with a resulting peak oxygen concentration much greater than a starting concentration (for example, at least 100-times greater).

(4) The peak concentration and total dose of oxygen that results from OUD into doped SiGe can be modulated by various means, described in detail, infra. As an overview, these means include:
a. A total dose of oxygen available in a silicon substrate, adjacent to a SiGe layer;
b. A temperature used for prebake; the prebake temperature also modulates available oxygen in adjacent layers;
c. A total dose of carbon (C) in SiGe;
d. A total dose of boron (B) in SiGe;
e. A total dose of fluorine (F) in SiGe;
f. Specific post-film-growth anneal temperature(s);
g. Specific anneal time(s);
h. A level of germanium (Ge) incorporation; and/or
i. SiGe layer thickness.

(5) The locational-position of an oxygen peak following OUD can be controlled by location of either boron and/or carbon profiles within the SiGe layer, and the germanium profile/shape.

(6) The width of the oxygen peak will take on a shape and width closely aligned to that of the boron and/or carbon profiles, and also that of the Ge profile.

Growth and in-situ doping techniques may be varied. Oxygen can be added in-situ during film growth or by ion implantation or diffusion techniques. Ion implantation and diffusion techniques are both known to a skilled artisan.

For example, ion implantation for OUD may be used at low energy (e.g., less than 1 keV) and low dose (e.g., less than 1E12 atoms/cm²) up to high energy (e.g., tens of MeV) and high dose (e.g., greater than 1E18 atoms/cm²). Additionally, various permutations of energy level and dosage may be applied.

Various films formation and dopant implant/diffusion techniques are known in the industry. Film formation techniques include molecular beam epitaxy (MBE) and chemical vapor deposition (CVD). CVD techniques include low pressure CVD (LPCVD), ultrahigh vacuum CVD (UHVCVD), rapid thermal CVD (RTCVD), atmospheric pressure CVD (APCVD), plasma-enhanced CVD (PECVD), high density plasma CVD (HDPCVD), and sub-atmospheric CVD (SACVD). Other techniques, also known in the art may be used with the OUD methodologies described. These techniques include metal organic CVD (MOCVD), laser-enhanced growth techniques, and ultraviolet-assisted growth techniques.

OUD into Strained SiGeC

In an exemplary embodiment, OUD may be utilized in strained silicon germanium carbon (SiC=GeC) to alter a base region electron minority carrier lifetime (τ_{nb}) of, for example, an NPN HBT. Altering the base minority carrier lifetime (τ_{nb}) effectively tunes base current, consequently tuning current gain. Such tuning is useful in the design of HBT devices. Ordinarily, advanced high-speed HBT devices have very thin base profiles and unreasonably high gains. A very high current gain leads to low collector-to-emitter breakdowns (BVCEO). Therefore, by purposely elevating oxygen, τ_{nb} is reduced and base recombination current (I_{rB}) is increased. Thus, the total base current (I_{B}) is increased and current gain (β) is reduced

$$( β = \frac{{I}_{C}}{{I}_{B}} ,$$

where I_{C} is collector current).

With reference to FIG. 1, a correlation plot 101 of minority carrier lifetime, Ε_{BO}, is plotted as a function of oxygen concentration. As indicated, note that oxygen concentrations of 10¹⁸ cm⁻³ or greater result in a minority carrier lifetime that is at 10⁻⁸ seconds and below. Mathematically, relationships between τ_{BO}, I_{rB}, and β may be expressed as

$${I}_{rB} = \frac{{Q}_{B}}{{τ}_{B 0}} = \frac{{Aqx}_{B} {n}_{p 0}}{2 {τ}_{B 0}} exp ( \frac{{v}_{BE}}{{v}_{t}} )$$

where Q_{B} is total base charge, A is emitter area; question is electron charge (1.6·10⁻¹⁹ Coulomb), x_{B} is the neutral base width, n_{pO} is minority carrier electron concentration inside the base, V_{BE} is base-to-emitter voltage, and Vₜ is a threshold voltage of the device.

Base recombination current adds to total base current, I_{B}, as
I_{B}=Iₚ+I_{rD}+I_{rB}−I_{O}
where Iₚ is base-emitter hole diffusion current, I_{rD} is base-emitter depletion region recombination current, and I_{O}is base-collector reverse saturation current.

Consequently, current gain, β, results from a ratio of collector to base currents

$$β = \frac{{I}_{C}}{{I}_{B}}$$

Thus, current gain is affected by base current, I_{B}.

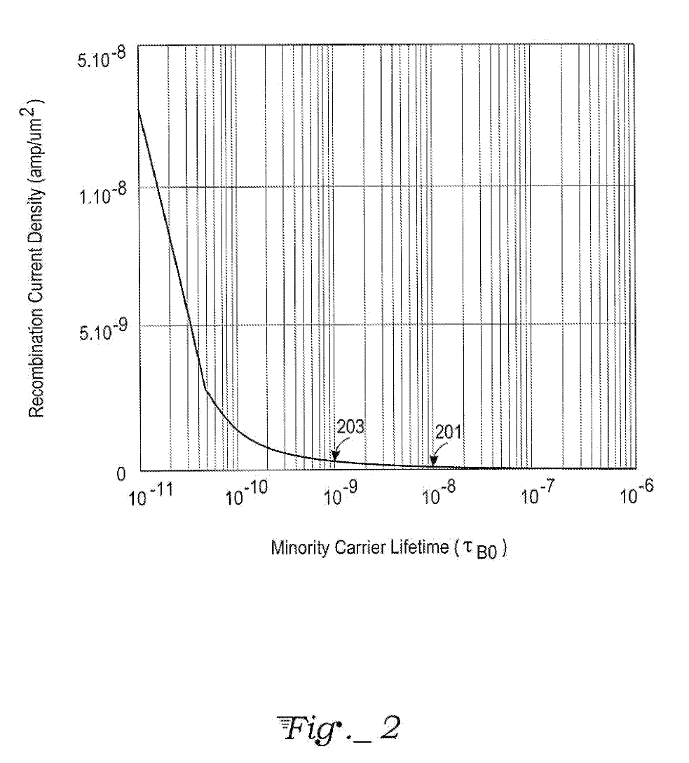

FIG. 2 relates recombination current density to minority carrier lifetime, τ_{BO}. With continued reference to FIGS. 1 and 2, at an oxygen concentration of 10¹⁸ atoms/cm³, corresponding to a τ_{BO} value of 10⁻⁸ seconds 201 (FIG. 2), the base recombination current density is starting to become modulated. For an oxygen concentration greater than 10¹⁸ atoms/cm³, I_{rB} will increase and current gain, β, will be reduced.

For example, an oxygen concentation of 8·10¹⁸ atoms/cm³ corresponds to a τ_{BO} value of 10⁻⁹ seconds 203 (FIG. 2). For lower τ_{BO} values, I_{rB} increases quickly.

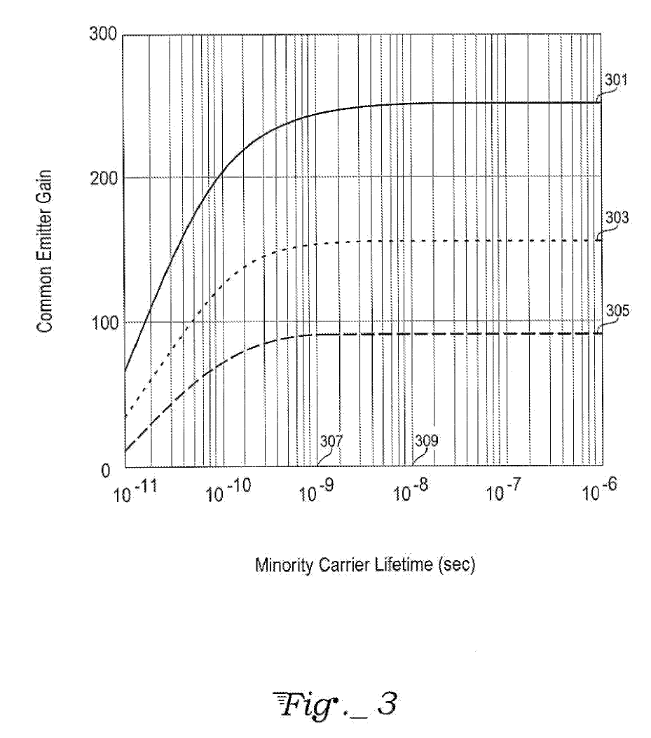

In FIG. 3, emitter gains are shown as a function of minority carrier lifetimes for three different transistor neutral base widths. The plots are indicative of 25 nm 301, 40 nm 303, and 70 nm 305 base widths. A breakpoint 307 occurs at an oxygen concentration of 10¹⁹ atoms/cm³. For oxygen concentration levels greater than 10¹⁸ atoms/cm³ (corresponding to 10⁻⁸ seconds 309) the current gain has reached a plateau in that any further increase in minority carrier lifetime results in substantially no further increase in common emitter gain.

Collector-emitter breakdown voltage is related to collector-to-base breakdown voltage and is further inversely proportional to the n^{th} root of current gain, β.

$$BVCEO = \frac{BVCBO}{\frac{1}{{β}_{n}}}$$

Therefore, as current gain is reduced, BVCEO will be increased. A value of ‘n’ is determined empirically for different material systems, but as a general rule for Si/SiGe hetero-materials, 3<n −6.

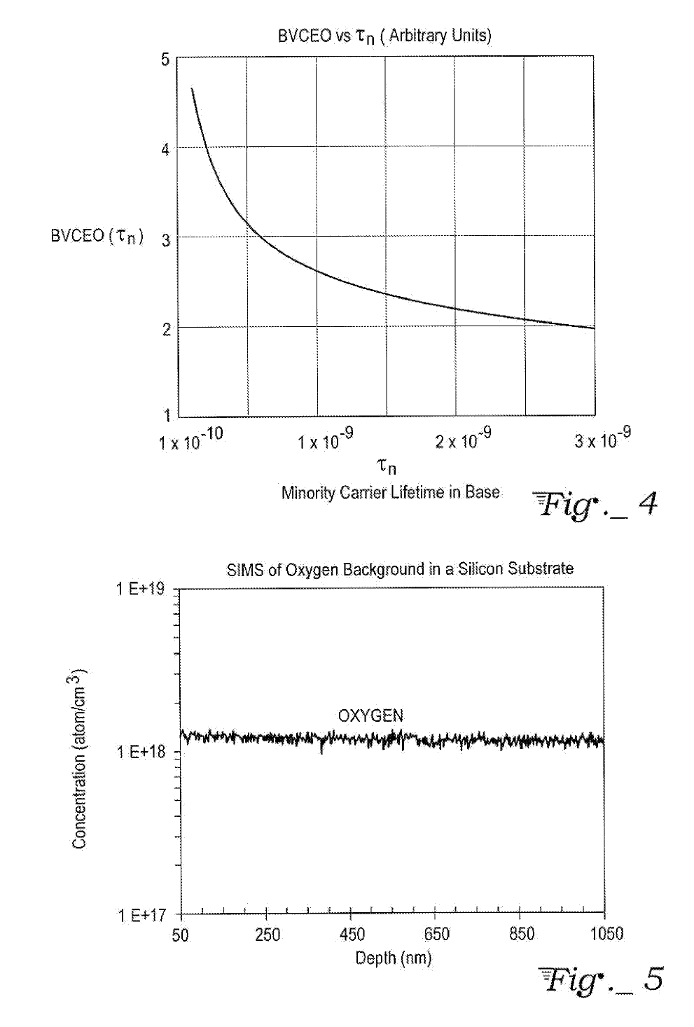

FIG. 4 illustrates an increase in BVCEO with a reduction in minority carrier lifetime, τₙ. (Units of BVCEO are in arbitrary units of volts). As seen from FIG. 4, below one nanosecond (10⁻⁹ seconds), BVCEO is affected by minority carrier lifetime. Recall that 10⁻⁹ seconds correlates to an oxygen concentration level of approximately 8·10¹⁸ atoms/cm³.

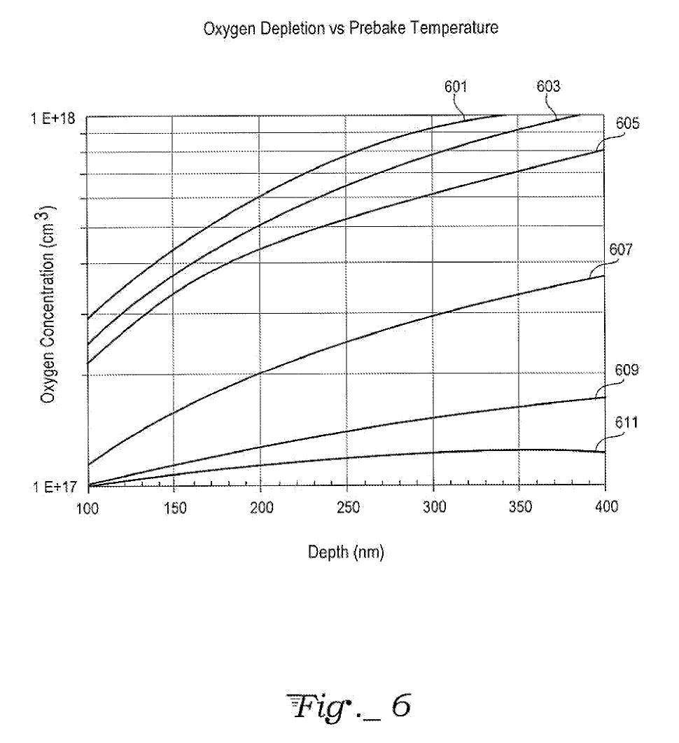

With reference to FIG. 5, oxygen concentration levels were measured following prebake in an underlying silicon substrate using secondary ion mass spectrometry (SIMS). The SIMS measurement confirmed expected theoretical results. The concentration of oxygen is relatively invariant over a wide range of depths (50 nm-1050 nm) into a surface of the Si substrate. The oxygen concentration level is about 1.1·10¹⁸ atoms/cm³.

As discussed previously, oxygen concentrations may be optimized or modulated by prebake temperature as part of the OUD process. In FIG. 6, oxygen is updiffused into SiGe in a precise amount by utilizing a prebake, carbon and baron concentration, in either a strained layer or pseudomorphic SiGe on silicon. The prebake temperatures depicted indicate a first curve 601 at 700° C., a second curve 603 at 800° C., a third curve 605 at 900° C., a fourth curve 607 at 1000° C., a fifth curve 609 at 1100° C., and a sixth curve 611 at 1200° C. Thus, oxygen is depleted more quickly from the surface of the substrate by increasing the prebake temperature. The prebake allows the substrate to outgas prior to any film formation.

In a specific exemplary embodiment, oxygen concentration levels were measured after an experimental method to determine oxygen depletion as a function of prebake temperature. The method employed included:

1. Provide a substrate with a fixed amount of oxygen (approximately 1.1·10¹⁸ atoms/cm³ for this specific test).

2. Perform a prebake to outgas oxygen from the surface of the substrate. The prebake may be utilized to modulate the supply of oxygen below the surface in order to achieve a predetermined oxygen updiffusion in subsequent steps.

3. Form an LPCVD growth of strained or lattice matched SiGe on top of the substrate.

4. Provide in-situ doping (during pseudomorphic growth) with carbopn and boron to a concentration level of 9·10¹⁹ atoms/cm³ and 1.2·10²⁰ atoms/cm³ respectively.

5. Form a silicon cap-layer (e.g., by CVD) on top of the SiGeC:B layer. The cap layer is grown at 750° C. to a thickness of 55 nanometers (nm).

6. Perform a thermal anneal at 900° C. for 60 seconds to achieve the amount of updiffusion as describer supra.

The peak oxygen concentration updiffused into SiGe is approximately 8·10¹⁸ atoms/cm³ and will correlate to minority carrier lifetime of about 1 nanosecond or less. If desired, greater updiffusion can be achieved by, for example, reducing the prebake temperature (thus depleting fewer oxygen atoms from the substrate), increasing oxygen concentration in the substrate, increasing carbon and/or boron dopant concentration in the SiGe, modulating the anneal time and/or temperature (time and temperature must be determined empirically for a given substrate, film stack, deposition method, etc.), and modulating the percentage of Ge (also empirically determined).

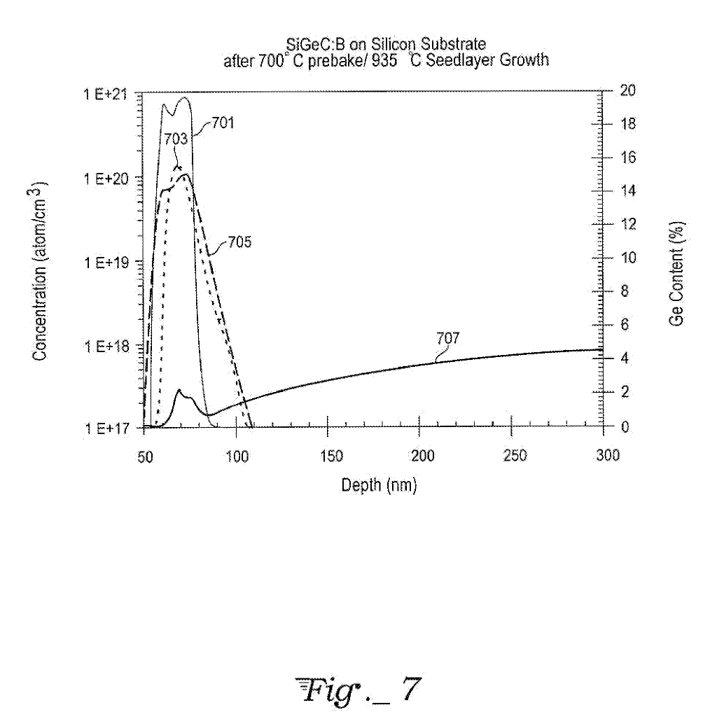

With reference to FIG. 7, an experimental run of as-grown SiGeC:B formed over a silicon substrate shows SIMS-generated concentration levels of Ge 701, B 703, C 705, and oxygen 707 as function of depth into the substrate. The SiGeC:B over Si received a 700° C. prebake and a 935° C. silicon seedlayer growth. The plot generated by SIMS indicates a box-like structure of the SiGeC:B layer.

The average Ge 701 content is 19.2% and was grown by LPCVD. The LPCVD growth was accomplished by thermal decomposition of silane (SiH₄) and germane (GeH₄) in a hydrogen ambient environment, with a growth temperaure of 600° C. and a process pressure of 100 Torr. Under the stated conditions, a growth rate of SiGC:B is approximately 3.5 angstroms (Å)/second. Carbon and boron are added in-situ, during growth, with methyl silane (CH₃SiH₃) as the carbon precursor, and diboran (B₂H₆) as the boron precursor. The carbon concentration as measured by SIMS is 9·10¹⁹ atoms/cm³, and the boron concentration similarly measured is 1.2·10²⁰ atoms/cm³. An x-ray diffraction measurement of the SiGeC:B film indicated a film thickness of 27 nm.

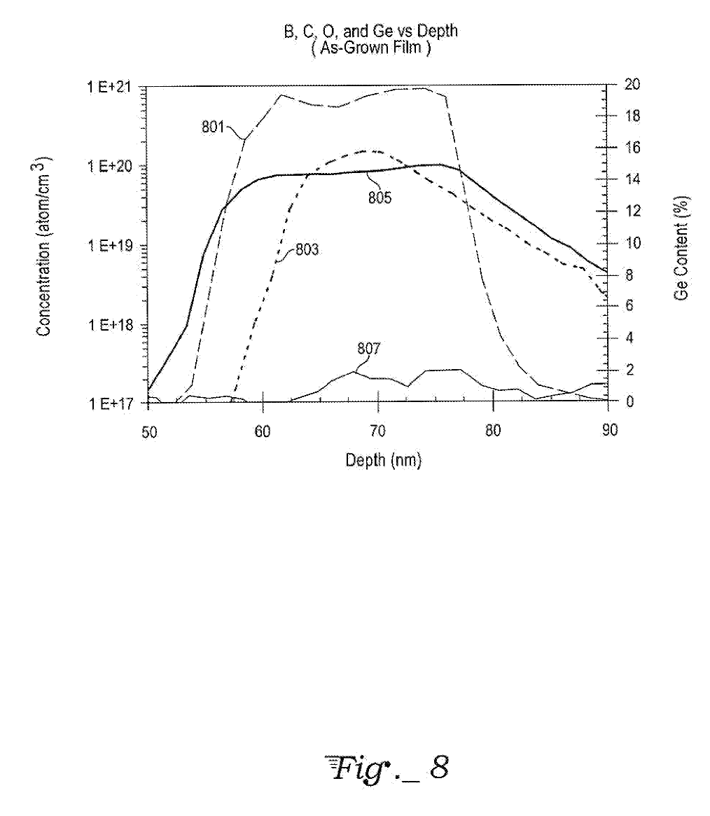

FIG. 8 indicates concentration levels of Ge 801, B 803, C 805, and oxygen 807 in the SiGeC:B as-grown film layer, prior to any thermal treatment to stimulate oxygen updiffusion. (The SIMS detection level is approximately 3·10¹⁷ atoms/cm³. Therefore, values of oxygen 807 detected below this level may be uncertain).

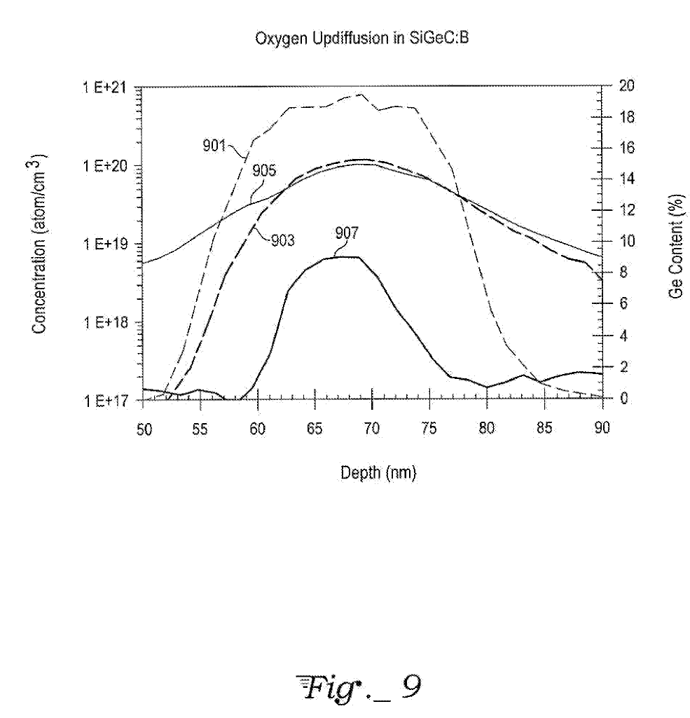

FIG. 9 illustrates oxygen updiffusion into the SiGeC:B layer after a 900° C., 60 second anneal and demonstrates that OUD causes oxygen to diffuse from the underlying substrate and into the overlying SiGeC:B film. The percentage of Ge 901 remained relatively constant as expected. Significantly, oxygen 907 updiffused to a level of about 8·10¹⁸ atoms/cm³ and has a profile closely aligned with the profiles of the Ge 901 and B 903 profiles. A final profile shown is C 905. Experimental results confirm that updiffusion of oxygen is enhanced by the presence of both C and B within the SiGe lattice. Note that OUD is enhanced if both C and B present are present but some level of OUD will still occur if either C or B is present.

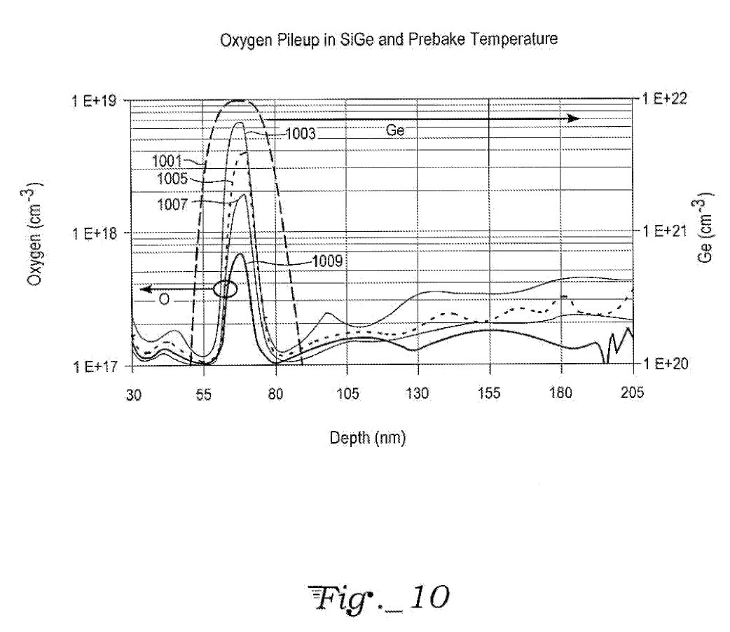

FIG. 10 illustrates an effect of prebake temperature on oxygen updiffusion. A concentration of Ge 1001 (at about 9.7·10²¹ atoms/cm³) indicates a relative location of oxygen with respect to the oxygen peak. One purpose for varying the prebake temperature is to modulate a supply of oxygen beneath the silicon substrate surface prior to film growth to study how available oxygen is the substrate affects the amount of oxygen that updiffuses following film growth and a subsequent post film growth thermal anneal.

With reference again to FIG. 6, as prebake anneal temperature increased, the oxygen beneath the silicon substrate surface is depleted. Thus, with increased prebake temperature, less oxygen is available beneath the surface (recall the prebake occurs before the SiGeC:B film is formed). Four silicon substrates, each with a starting background oxygen concentration of 1·10¹⁸ atoms/cm³ were prebaked. Each of the four substrates was prebaked at a different temperature: the first at 700° C., the second at 900° C., the third at 1000° C., and the fourth at 1100° C. After the prebake, each of the four substrates had a SiGeC:B film formed on its sureface by LPCVD. Following the film formation, each substrate received a post film growth anneal of 900° C. for 60 seconds. The post film growth anneal initiated and sustained OUD from the substrates and into the SiGeC:B film. Results indicated that peak oxygen levels, observed by SIMS, following the post growth anneal of 900° C. for 60 seconds is a function of prebake temperature. The prebake outgases oxygen from the silicon substrate and hence modulates the quantity of oxygen that is grown and then annealed again to initiate and sustain the OUD process.

With reference back again to FIG. 10, a first plot 1003 indicates the substrate receiving the 700° C. prebake, a second plot 1005 indicates the substrate receiving the 900° C. prebake, a third plot 1007 indicates the substrate receiving the 1000° C. prebake, and a fourth plot 1009 indicates the substrate receiving the 100° C. prebake.

General Applications of OUD

The aforementioned embodiment of a film/substrate combination exemplifies a particular application for the present invention. A person of skill in the art can readily envision numerous other related applications in the semiconductor and allied industries where an ability to locate oxygen in a film or other layer could be highly advantageous.

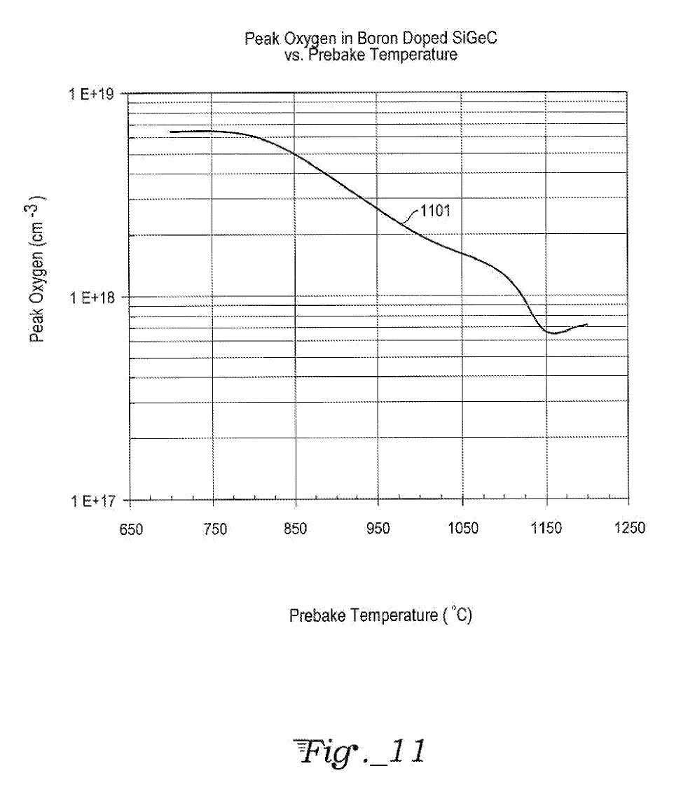

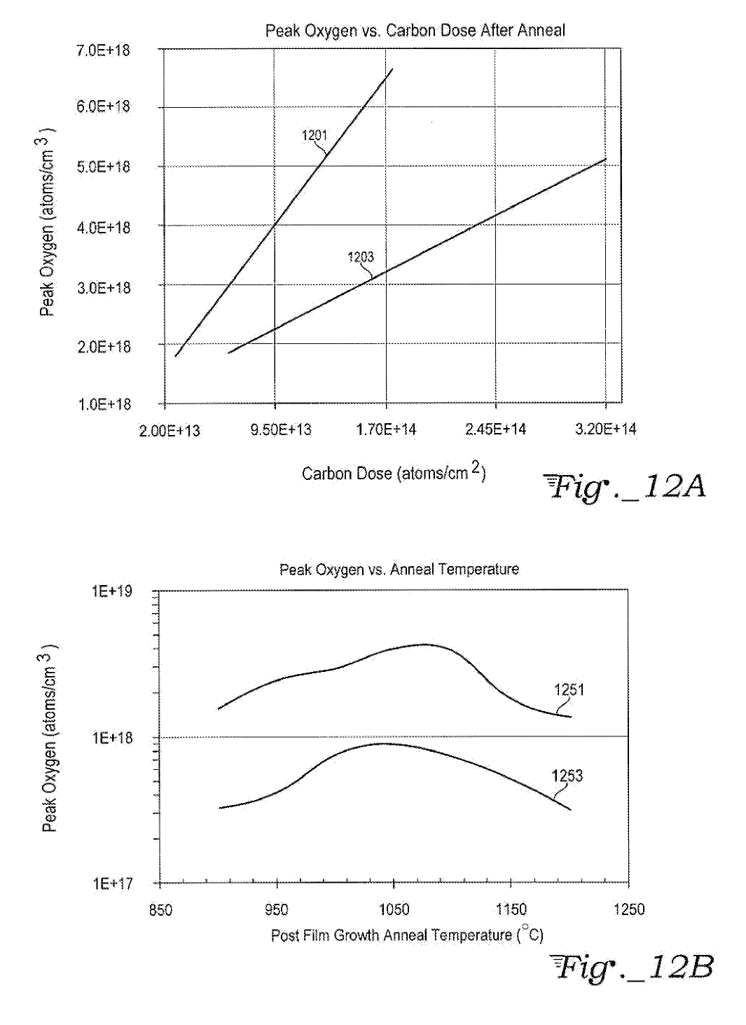

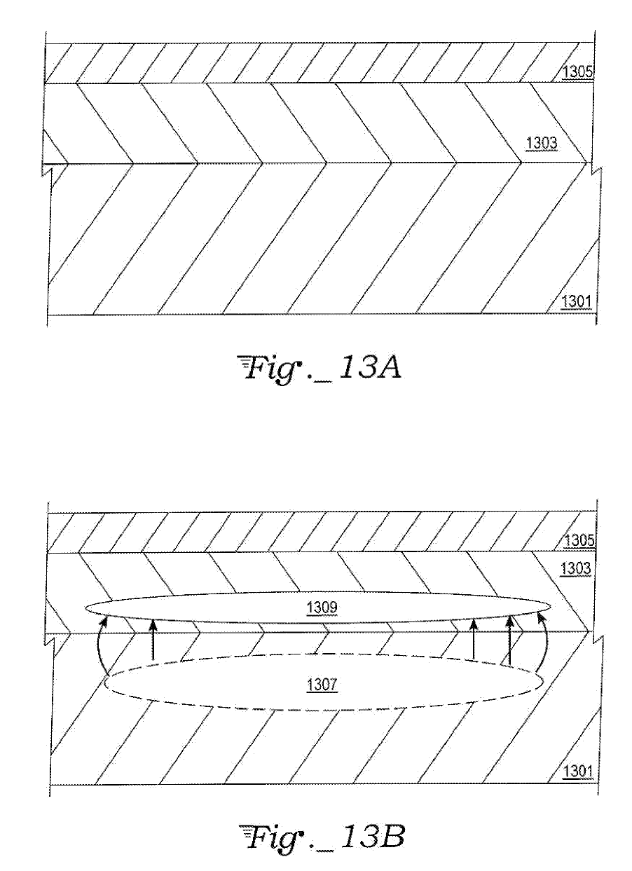

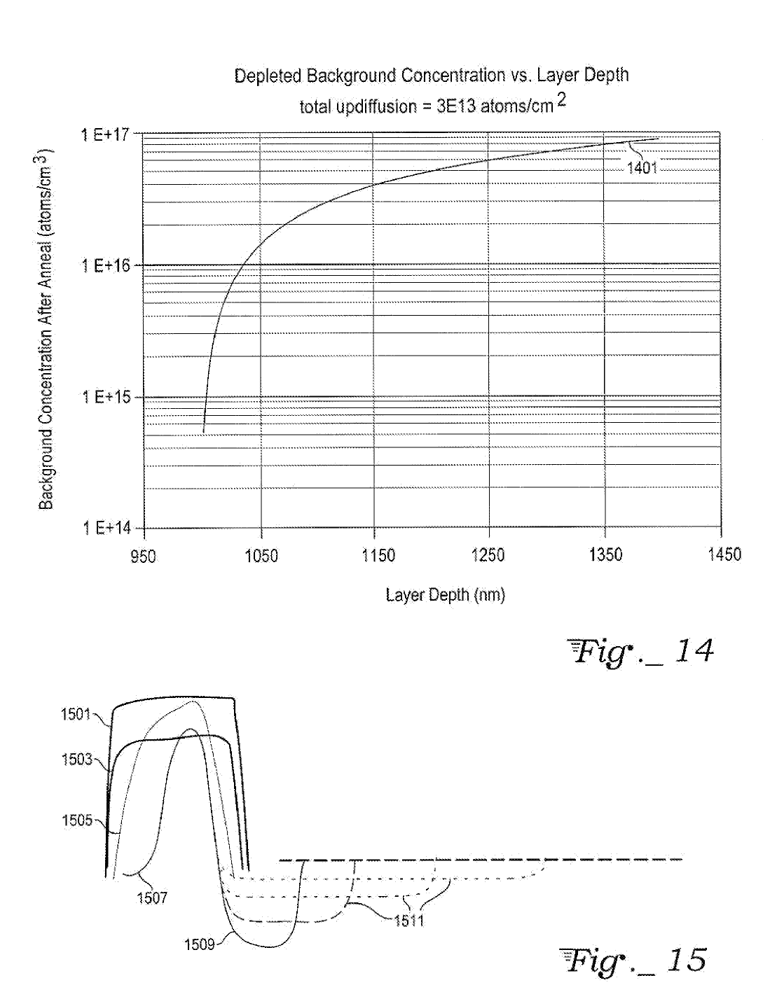

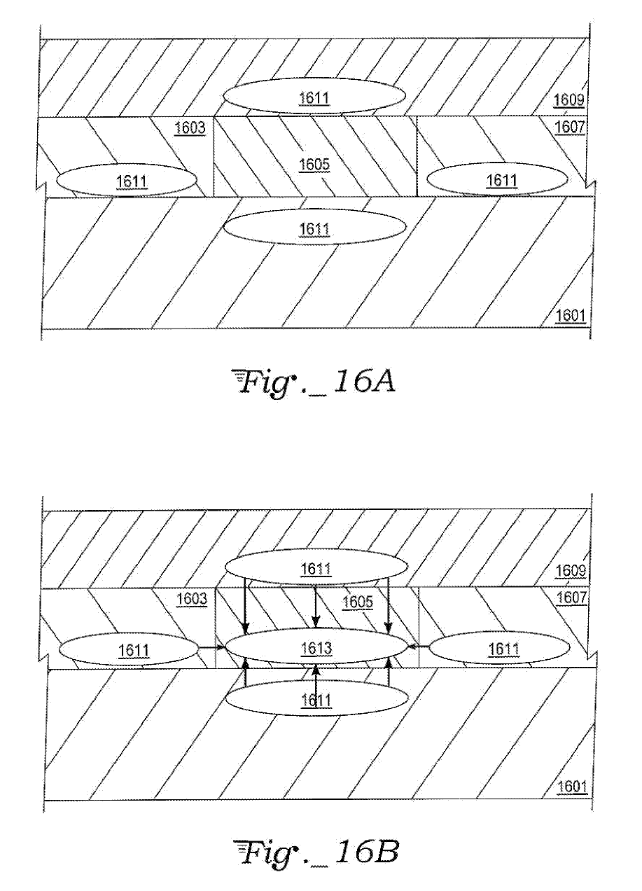

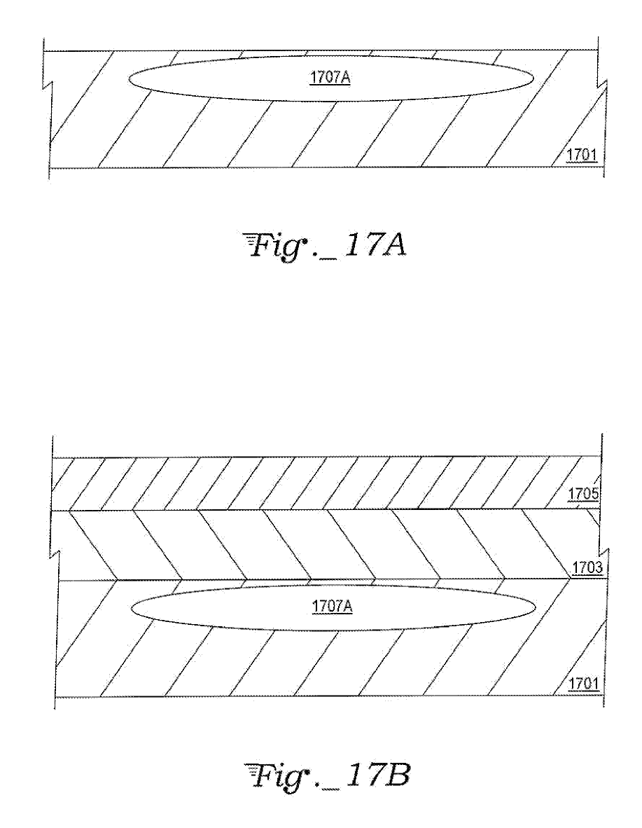

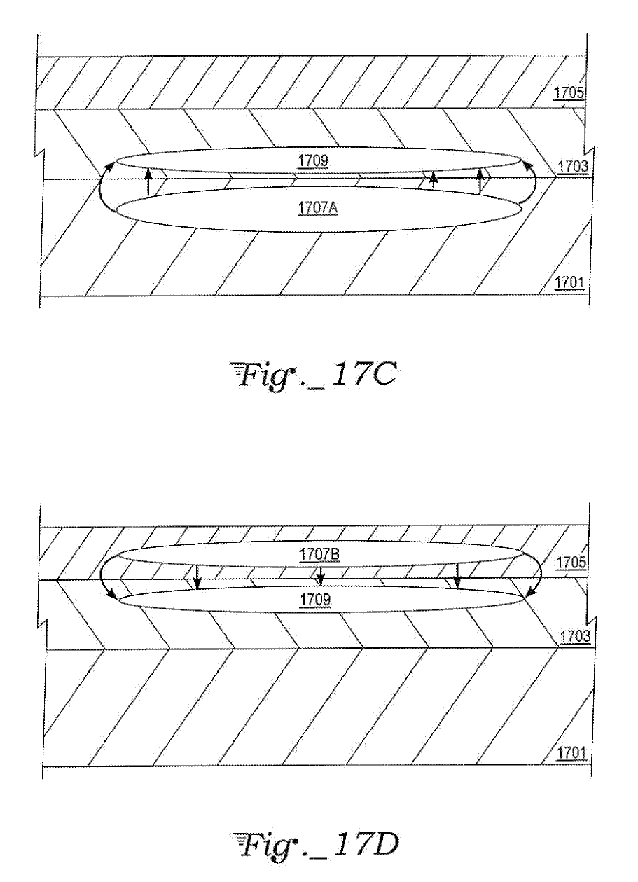

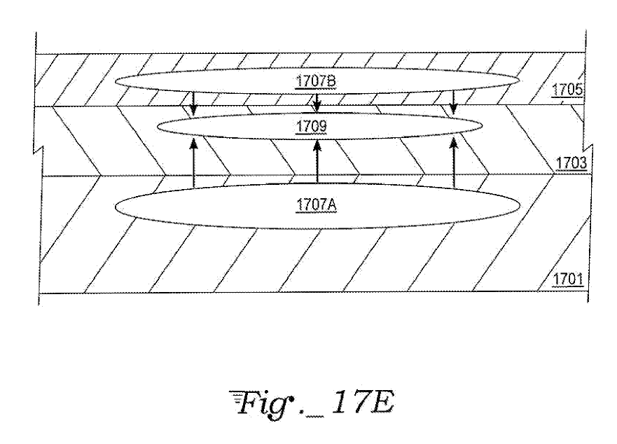

FIG. 11 illustrates a trend line 1101 in peak oxygen concentration levels versus prebake temperature in a boron doped SiGeC film. FIG. 12A illustrates two sample sets; both sets indicate peak oxygen concentration as a function of carbon dose after a post film growth anneal. A first sample set 1203 contains 20% Ge. A second sample set 1201 contains 13.5% Ge. Both sets are SiGe profiles that are approximately 27 nm thick and boron doped to a level of 1.2·10²⁰ atoms/cm³. Carbon dose levels are varied in each sample set from 2·10¹³ atoms/cm² to 3.2·10¹⁴ atoms/cm². As indicated in FIG. 12A, the percentage of Ge affects the sensitivity of the oxygen updiffusion to the total carbon dose. In this case, reducing the percentage of Ge to 13.5% from 20% results in greater sensitivity to carbon as indicated by the second sample set 1201 indicating the peak oxygen concentration versus carbon dose.

FIG. 12B illustrates peak oxygen due to OUD as a function of post film growth anneal temperatures for two sample sets of film-on-silicon substrates. A first sample set 1251 received an 800° C. prebake anneal. A second sample set 1253 received a 1200° C. prebake anneal. Consequently, each set had a different amount of oxygen available for updiffusion at a surface of each silicon substrate (with reference again to FIG. 6). The post films growth anneal provides thermal energy to initiate and sustain the OUD process. FIG. 12B thus illustrates the amount of oxygen that is updiffused is a function of both the post growth anneal as well as the prebake anneal treatment.

FIG. 12B additionally illustrates two regions of interest with respect to oxygen updiffusion. OUD is enhanced in a temperture range from about 900° C. to either 1000° C. or 1150° C. (depending on the sample set), and falls off as temperature is increased above 1000° C. or 1150° C. (depending on the sample set).

Thus, if profived with a material with a predetermined oxygen concentration level, the amount of oxygen updiffused into, for example, SiGeC:B can be modulated in various ways. The amount of oxygen updiffused can be modulated with prebake temperature as illustrated in FIGS. 10 and 11, or by the total carbon concentration as indicated in FIG. 12A, or by the amount of Ge added to the silicon lattice also as shown in FIG. 12A. Further, as indicated by FIG. 12B, a post film growth anneal temperature will also affect the amount of oxygen updiffused into an overlying film.

As described herein, prebake temperature (i.e., a temperature affecting total available oxygen in an adjacent layer), a total dose of carbon, post film growth anneal conditions correlate to the total quantity of oxygen that can be updiffused. Also, the percentage of incorporated Ge correlates to the sensitivity of the process to oxygen updiffusion.

OUD-based Laser Diode Fabrication

In another exemplary embodiment, oxygen updiffusion can effectively be utilized in the construction of a silicon based laser diode. In a specific exemplary embodiment, OUD can be applied to fabrication of silicon nanocrystal light emitting diodes (LEDs). An oxygen layer that is created with updiffusion can assist in formation of a “recombination zone” to enhance photon emission. Further, oxygen is important as a co-dopant with Erbium (Er) to prevent formation of inactive Er complexes. An ability to “updiffuse” oxygen, as opposed to other methods such as ion implantation, assists in reducing lattice damage. Reduced lattice damage enhances crystalline quality, thus reducing crystalline defects that might hinder the lasing action of an Er silicon nanocrystal (si—nc) laser.

Referring again to FIG. 9, the oxygen profile 907 is shown to be no more than 50 to 100 Å(5-10 nm) in width at full-width half-maximum (FWHM). An ability to updiffuse and confine oxygen to particular boundaries has important device implications for nanotechnologies in general as discussed herein. Such implications are especially true for SiGe HBTs which utilize “nano-thin” layers as developed in following sections.

Methods of Utilizing OUD to Form Oxygen Depleted Layers

With reference to FIG. 13A, one exemplary OUD method begins with a semiconductor substrate 1301. The semiconductor substrate 1301 may be comprised of various semiconductor types of materials such as silicon, SiGe, Ge, or other types of elemental or compound semiconductors. The semiconductor substrate 1301 contains an oxygen concentration at some level due to, for example, an oxygen background remaining from silicon ingot manufacturing or from process-related contamination.

A SiGe layer 1303 is formed over the semiconductor substrate 1301. The SiGe layer 1303 may be formed by various methods described supra such as MBE or various types of CVD. The SiGe layer 1303 is doped (e.g., by implantation, diffusion, or in-situ during the film formation process) with boron, carbon, or other dopant materials. Adding Ge to a semiconductor lattice structure (e.g., a silicon lattice), even at very low quantities (e.g., less than 1%) results in an enhancement of the solid solubility of OUD facilitating species such as boron and/or carbon.

An optional semiconductor cap layer 1305 may then be formed over the SiGe layer 1303. The semiconductor cap layer 1305 may be comprised of various elemental or compound semiconducting materials (e.g., Si, SiGe, Ge, etc.). The semiconductor cap layer 1305 also contains some level of oxygen concentration due to, for example, process-induced contamination. A thickness of the semiconductor cap layer 1305 may be anywhere from less than 10 Å(1 nm) in thickness up to several microns, depending on technology requirements. Ge may be added to the optional semiconductor cap layer 1305 in any percentage from near 0% up to very high concentrations of 100%.

Once any film layer(s) is formed, an anneal step is conducted. The anneal step may be based on various temperatures as discussed supra with regard to FIG. 12B. In a specific exemplary embodiment, the anneal temperature is carried out at a temperature greater than 900° C. for times of from 1 second (flash anneal) up to times greater than 1 minute. A temperature-time product to achieve a required OUD to achieve an oxygen depleted zone is dependent on an exact device type combined with various materials used, dopant levels and so on. Therefore, time-temperature products can be determined experimentally. Further, anneal temperatures less than 900° C. may also be employed.

Arrows in FIG. 13B indicate a direction of oxygen updiffusion from the underlying semiconductor substrate 1301 into overlying SiGe layer 1303. Although not indicated in FIG. 13B, oxygen contained in the optional semiconductor cap layer 1305 above the SiGe layer 1303 will diffuse down into the underlying SiGe layer 1303. Thus, the optional semiconductor cap layer 1305 will be depleted of oxygen during the anneal step as well as the semiconductor substrate 1301.

OUD Effectiveness

Effectiveness of the OUD process can be demonstrated by means of a specific exemplary embodiment. In this embodiment (not shown), a 30 nm thick SiGe film with 18% Ge is formed over a silicon substrate. The silicon substrate has a background oxygen concentration level of 1·10¹⁷ atoms/cm³ following a prebake anneal. During film growth, the SiGe film is in-situ doped with carbon to a concentration level of 3·10²⁰ atoms/cm³ and with boron to a concentration level of 1·10²⁰ atoms/cm³. The SiGeC:B film is subsequently annealed at 900° C. for 90 seconds.

In this specific embodiment, SIMS measurements revealed an oxygen updiffusion to a concentration that is approximately 100 times greater than the adjacent background concentration level of 1·10¹⁷ atoms/cm³ with a total updiffused oxygen dose of 3·10¹³ atoms/cm². If the beginning oxygen background concentration level in the underlying layer is 1·10¹⁷ atoms/cm³, the updiffusion of a dose of 3·10¹³ atoms/cm² results in a final “theoretical” background concentration that is reduced to the following peak concentrations as a function of underlying layer thickness.

Calculation of background oxygen depletion as a function of layer depth is approximately as follows. Set a dosage level, D, equal to the total dose updiffused with the above conditions
D=3·10¹³ atoms/cm²
A change in oxygen background concentration, dC, is
dC=Cₛₜₐᵣₜ-C_{end}
where Cₛₜₐᵣₜ and C_{end} are starting and ending background concentrations, respectively. A layer depth or thickness, t_{sub}, is

$$dC = \frac{D}{{t}_{sub}}$$

Substituting variables,

$${C}_{start} - {C}_{end} = \frac{D}{{t}_{sub}}$$

$${C}_{end} = {C}_{start} - \frac{D}{{t}_{sub}}$$

Recall that C_{end} is the background concentration after OUD has taken place and results from these calculations are shown graphically in FIG. 14. FIG. 14 shows background concentration (C_{end}) 1401 for various adjacent layer thicknesses illustrating the amount of depletion that occurs due to oxygen updiffusion into SiGeC:B during thermal anneal.

With reference to FIG. 15, an exemplary concept of “deep depletion” is illustrated along with a formation of oxygen depleted regions in an adjacent film layers (i.e., adjacent to SiGe doped with boron and/or carbon). FIG. 15 includes a Ge profile 1501 (with Ge at a concentration of 18%), a carbon profile 1503 (C concentration is 3·10²⁰ atoms/cm³), a boron profile 1505 (B concentration is 1·10²⁰ atoms/cm³), and an oxygen updiffusion profile 1507 (the oxygen peak concentration is at 1·10¹⁹ atoms/cm³ based on a total oxygen dose of 3·10¹³ atoms/cm²). A deep depletion 1509 occurs over a shallow or thin layer region while areas with less depletion 1511 occur as depth is increased.

The Ge profile 1501 is a box shape although other shapes such as trapezoid, triangle, or shapes with curvature may be utilized. Such profile shapes and their fabrication are known to one of skill in the art. The carbon profile 1503 is shown throughout the SiGe layer, although carbon position can be varied. The boron profile 1505 is shown at the center, but can be placed anywhere. Overall, a skilled artisan will realize that FIG. 15 is illustrative only. The Ge, B, and C concentrations can be varied over very wide ranges to achieve a wide range of OUD.

Oxygen depleted regions enhance a purity level of the adjacent film layers. The purity level is important for building low-defectivity zones during fabrication of electronic, phonic, micro-electro-mechanical systems (MEMS), and nano-devices. Also, the purity level is important for fabrication of silicon-on-insulator (SOI) substrates with very high purity ultra-thin active layers. Further, additional applications of adding oxygen to Si, SiGe, or Ge layers (i.e., the layer into which the oxygen updiffuses), is significant for purposely providing generation/recombination centers (important for tuning electronic devices such as SiGe HBTs and construction of laser diodes) and providing added stability to metastable layers of SiGe and/or Ge on Si, SiGe, or Ge substrates.

With reference to FIG. 16A, another exemplary embodiment illustrates formation of film layers to facilitate OUD. This exemplary OUD method begins with a semiconductor substrate 1601. The semiconductor substrate 1601 may be comprised of various semiconducting types of materials such as silicon, SiGe, Ge, or other types of elemental or compound semiconductors. The semiconductor substrate 1601 contains an oxygen background concentration 1611 at some level due to, for example, an oxygen background remaining from silicon ingot manufacturing or from process-related contamination.

A first 1603 and second 1607 semiconductor region is formed over the semiconductor substrate 1601. The first 1603 and second 1607 semiconductor regions may be comprised of various types of semiconductor materials such as Si or SiGe. The first 1603 and second 1607 semiconductor regions may be formed by various methods described supra such as MBE or various types of CVD, and may contain background oxygen due to process contamination.

Formation of a third semiconductor region 1605 may involve a selective growth process involving oxide formation in the first 1603 and second 1607 semiconductor regions, prior to formation of the third semiconductor region 1605. Oxide removal then occurs in the first 1603 and second 1607 semiconductor regions, following by growth of SiGe (or Si or Ge) in the first 1603 and second 1607 semiconductor regions. One skilled in the art will recognize that selective growth techniques are not the only methods that can be utilized to accomplish the basic structure below, but are specific exemplary embodiments. The third semiconductor region 1605 is doped in-situ with, for example, B and C. Additionally, fluorine functions similarly to B or C as an aid to oxygen updiffusion.

The third semiconductor region 1605 is formed over the semiconductor substrate 1601 and between the first 1603 and second 1607 semiconductor regions. The third semiconductor region 1605 is comprised of SiGe and may be formed by various methods described supra such as MBE or various types of CVD. The third semiconductor region 1605 is doped (e.g., by implantation or diffusion) with boron, carbon, or other dopant materials.

An optional semiconductor cap layer 1609 may then be formed over the underlying semiconductor regions 1603, 1605, 1607. The semiconductor cap layer 1609 may be comprised of various elemental or compound semiconducting materials (e.g., Si, SiGe, Ge, etc.). The semiconductor cap layer 1609 also contains some level of oxygen concentration due to, for example, process-induced contamination. A thickness of the semiconductor cap layer 1609 may be anywhere from less than 10 Å(1 nm) in thickness up to several microns, depending on technology requirements. Ge may be added to the optional semiconductor cap layer 1609 in any percentage from near 0% up to very high concentrations of 100%. Adding Ge to a semiconductor lattice structure (e.g., a silicon lattice), even at very low quantities (e.g., less than 1%) results in an enhancement of the solid solubility of OUD facilitating species such as boron and/or carbon.

With the exception of the third semiconductor region 1605, each of the other semiconductor regions 1603, 1607, 1609 and the semiconductor substrate 1601 contain some level of oxygen background concentration 1611. (Note that the quantitative level of oxygen background is not necessarily the same in each of the four areas of oxygen background concentration 1611. The levels may be different from each other but are merely labeled the same for clarity).

Once any film layer(s) are formed, an anneal step is conducted. The anneal step may be based on various temperatures as discussed with supra with regard to FIG. 12B. In a specific exemplary embodiment, the anneal temperature is carried out at a temperature greater than 900° C. for times of from 1 second (flash anneal) up to times greater than 1 minute. A temperature-time product to achieve a required OUD to achieve an oxygen depleted zone is dependent on an exact device type combines with various materials used, dopant levels and so on. Therefore, time-temperature products can be determined experimentally. Further, anneal temperatures less than 900° C. may also be employed.

Arrows in FIG. 16B indicate a direction of oxygen updiffusion from the underlying semiconductor substrate 1601, the first 1603 and second 1607 semiconductor regions, and the optional semiconductor cap layer 1609 into the third semiconductor region 1605. Thus, the direction of oxygen updiffusion into the third semiconductor region 1605 is from underlying, overlying, and side-by-side layers.

Utilizing OUD for Formation of Oxygen Rich Layers

With reference to FIG. 17A, another exemplary embodiment illustrates formation of film layers to facilitate OUD. This exemplary OUD method begins with a semiconductor substrate 1701. The semiconductor substrate 1701 may be comprised of various semiconducting types of materials such as silicon, SiGe, Ge, or other types of elemental or compound semiconductors.

An oxygen source 1707A may be supplied from an as-grown silicon ingot in the case of the semiconductor substrate 1701 being comprised of silicon, such as occurs with Czochralski (CZ) grown silicon ingots. Additionally, the oxygen source 1707A may be purposefully added to the semiconductor substrate 1701. The oxygen source 1707A may be added by various means known in the art such as by implantation or chemical vapor deposition (CVD).

In FIG. 17B, a SiGe layer 1703 is formed over the semiconductor substrate 1701. The SiGe layer 1703 may be formed by various methods described supra such as MBE or variouse types of CVD. The SiGe layer 1703 is doped (e.g., by implantation or diffusion) with boron, carbon, or other dopant materials. Adding Ge to a semiconductor lattice structure (e.g., a silicon lattice), even at very low quantities (e.g., less than 1%) results in an enhancement of the solid solubility of OUD facilitating species such as boron and/or carbon.

An optional semiconductor cap layer 1705 may then be formed over the SiGe layer 1703. The semiconductor cap layer 1705 may be comprised of various elemental or compound semiconducting materials (e.g., Si, SiGe, Ge, etc.). The semiconductor cap layer 1705 may contain some level of oxygen concentration due to, for example, process-induced contamination. (Additionally, as will be described infra, the semiconductor cap layer 1705 may have oxygen purposefully added). A thickness of the semiconductor cap layer 1705 may be anywhere from less than 10 Å(1 nm) in thickness up to several microns, depending on technology requirements. Ge may be added to the optional semiconductor cap layer 1705 in any percentage from near 0% up to very high concentrations of 100%.

Once any film layer(s) is formed, an anneal step is conducted. The anneal step may be based on various temperatures as discussed supra with regard to FIG. 12B. In a specific exemplary embodiment, the anneal temperature is carried out at a temperature greater than 900° C. for times of from 1 second (flash anneal) up to times greater than 1 minute (e.g., depending upon a required amount of updiffusion and depending on various film thicknesses, etc., times measured in hours may be used). A temperature-time product to achieve a required OUD to achieve an oxygen depleted zone is dependent on an exact device type combined with various materials used, dopant levels and so on. Therefore, time-temperature products can be deterrmined experimentally. Further, anneal temperatures less than 900° C. may also be employed. In FIG. 17C, arrows indicate movement or oxygen updiffusion from the oxygen source area 1707A to an oxygen updiffusion area 1709 located within the SiGe layer 1703 during the anneal process.

In a modification of the exemplary embodiment shown in FIG. 17D, the semiconductor cap layer 1705 has an oxygen source 1707B purposefully added to the semiconductor cap layer 1705. As described supra, the oxygen source 1707B may be added by various means known in the art such as by implantatikon or chemical vapor deposition (CVD). Arrows indicate movement or oxygen updiffusion from the oxygen source area 1707B to the oxygen updiffusion area 1709 located within the SiGe layer 1703 during an anneal process.

In another modification of the exemplary embodiment shown in FIG. 17E, two oxygen source areas 1707A, 1707B are provided. The two oxygen source areas 1707A, 1707B are located in the semiconductor substrate 1701 and the semiconductor cap layer 1705 respectively. During an anneal process, updiffusion occurs from both of the two oxygen source areas 1707A, 1707B into the oxygen updiffusion area 1709 located within the SiGe layer 1703.

Further Considerations and Modifications of OUD

Depending upon a particular device type, a final location of incorporated oxygen may affect device characteristics and performance. Oxygen may be placed at any given location with the film layer(s) depending on the type of device application and the requirements of the technology by applying the OUD method detailed herein. Further, a skilled artisan may readily identify modifications of the OUD method not specifically detailed but within a scope of the present invention as explicitly and impliedly described. For example, oxygen may be placed throughout all SiGe layers in a predetermined quantity to both inhibit boron diffusion and to mitigate formation of gliding defects within the lattice. The oxygen will also increase base recombination due to electrically active defects within the neutral base region, thereby reducing current gain, and increasing the BVCEO.

Alternatively, oxygen may be placed only in a spacer or setback layer(s) (not shown) in a predetermined quantity, but not in a neutral base region (boron doped region). This type of placement allows mitigating gliding defects and higher Ge incorporation, but will minimize the oxygen effect on recombination current in the neutral base (i.e., no oxygen in the boron doped layer), thus allowing for higher current gains depending upon device requirements. Due to the selectability of location and quantity, device parameters such as base recombination, current gain, and breakdowns can be tailored to meet specific device performance requirements. Devices other than HBTs and LEDs can readily benefit from OUD methods as well.

Although the present invention is described in terms of exemplary embodiments, a skilled artisan will realize that techniques described herein can readily be adapted to other forms of fabrication techniques and devices. For example, the OUD techniques could be applied to other technologies such as FinFET, surround gate FET, vertical thin film transistors (VTFT), hyper-abrupt junctions, resonant tunnel diodes (RTD), and optical waveguides for photonics. Also, the choice of substrate is not limited necessarily to semiconductor materials, such as silicon. Other materials, such as non-semiconducting materials or non-conductive materials (e.g., a quartz photomask or a polyethyleneterephthalate (PET) substrate used in PDAs and cellular phones) may be readily incorporated as well, especially when the oxygen is supplied from other film layers. Therefore, profiles, thicknesses, and concentrations of, for example, a strain-compensated metastable SiGe layer can be selected to accommodate a variety of needs. The metastable SiGe layer could also be strain-compensated with other elements, which may induce a diminished diffusivity for a given dopant type.

Also, although exemplary process steps and techniques are described in detail, a skilled artisan will recognize that other techniques and methods may be utilized, which are still included within a scope of the appended claims. For example, there are several techniques used for depositing and doping a film layer (e.g., chemical vapor deposition, plasma-enhanced chemical vapor deposition, molecular beam epitaxy, atomic layer deposition, etd.). Although not all techniques are amenable to all film types described herein, one skilled in the art will recognize that multiple and alternative methods may be utilized for depositing or otherwise forming a given layer and/or film type.

Additionally, many industries allied with the semiconductor industry could make use of the OUD technique. For example, a thin-film head (TFH) process in the data storage industry, an active matrix liquid crystal display (AMLCD) in the flat panel display industry, or the micro-electromechanical-systems (MEMS) industry could readily make use of the processes and techniques described herein. The term “semiconductor” should thus be recognized as including the aforementioned and related industries. The drawing and specification are, accordingly, to be regarded in an illustrative rather than a restrictive sense.

What is claimed is:

1. A method for fabricating a compound semiconductor film, the method comprising:
providing a semiconductor substrate having a first surface;
incorporating a quantity of oxygen into the semiconductor substrate;
forming a compound semiconductor film over the first surface of the substrate, the compound semiconductor film containing a dopant element;
annealing the semiconductor substrate and the compound semiconductor film; and
controlling movement of the oxygen from the semiconductor substrate into the compound semiconductor film.

2. The method of claim 1 wherein the dopant element is selected to be carbon.

3. The method of claim 1 wherein the dopant element is selected to be boron.

4. The method of claim 1 wherein the dopant element is selected to be fluorine.

5. The method of claim 1 wherein the step of controlling the movement of the oxygen is accomplished by controlling a profile of the dopant.

6. The method of claim 1 wherein the step of controlling the movement of the oxygen is accomplished by controlling a temperature of the annealing step.

7. The method of claim 6 wherein the temperature is selected to be about 900° C.

8. The method of claim 1 wherein the step of controlling the movement of the oxygen is accomplished by controlling a time of the annealing step.

9. The method of claim 1 wherein the compound semiconductor film is selected to be silicon germanium.

10. The method of claim 9 wherein the step of controlling the movement of the oxygen is accomplished by controlling a profile of the germanium.

11. The method of claim 9 wherein the step of controlling the movement of the oxygen is accomplished by controlling a percentage of the germanium used in the silicon germanium film.

12. The method of claim 1 wherein the step of controlling the movement of the oxygen is accomplished by controlling a quantity of the oxygen incorporated into the semiconductor substrate.

13. The method of claim 1 wherein the semiconductor substrate is selected to be silicon.

14. The method of claim 13 wherein the quantity of oxygen is incorporated by growing a silicon ingot to produce the semiconductor substrate by Czochralski ingot formation.

15. The method of claim 1 wherein the quantity of oxygen is incorporated by chemical vapor deposition.

16. The method of calim 1 wherein the oxygen is incorporated by ion implantation.

17. A method for fabricating a compound semiconductor film, the method comprising:
providing a substrate having a first surface;
forming a compound semiconductor film over the first surface of the substrate, the compound semiconductor film containing a dopant element;
forming a semiconductor cap layer over the compound semiconductor film;
incorporating a quantity of oxygen into the semiconductor cap layer;
annealing the substrate, the compound semiconductor film, and the semiconductor cap layer; and
controlling movement of the oxygen from the semiconductor cap layer into the compound semiconductor film.

18. The method of claim 17 wherein the dopant element is selected to be carbon.

19. The method of claim 17 wherein the dopant element is selected to be boron.

20. The method of claim 17 wherein the dopant element is selected to be fluorine.

21. The method of claim 17 wherein the step of controlling the movement of the oxygen is accomplished by controlling a profile of the dopant.

22. The method of claim 17 wherein the step of controlling the movement of the oxygen is accomplished by controlling a temperature of the annealing step.

23. The method of claim 22 wherein the temperature is selected to be about 900° C.

24. The method of claim 17 wherein the step of controlling the movement of the oxygen is accomplished by controlling a time of the annealing step.

25. The method of claim 17 wherein the compound semiconductor film is selected to be silicon germanium.

26. The method of claim 25 wherein the step of controlling the movement of the oxygen is accomplished by controlling a profile of the germanium.

27. The method of claim 25 wherein the step of controlling the movement of the oxygen is accomplished by controlling a percentage of the germanium used in the silicon germanium film.

28. The method of claim 17 wherein the step of controlling the movement of the oxygen is accomplished by controlling a quantity of the oxygen incorporated into the semiconductor cap layer.

29. The method of claim 17 wherein the quantity of oxygen is incorporated by chemical vapor deposition.

30. The method of claim 17 wherein the quantity of oxygen is incorporated by ion implantation.

31. A method for fabricating a compound semiconductor film, the method comprising:
providing a substrate having a first surface;
forming a compound semiconductor film over a first portion of the first surface of the substrate, the compound semiconductor film containing a dopant element;
forming at least one additional semiconductor layer over a second portion of the substrate and next to the compound semiconductor film;
incorporating a quantity of oxygen into the at least one additional semiconductor layer;
annealing the substrate, the compound semiconductor film, and the at least one additional semiconductor layer; and
controlling movement of the oxygen from the at least one additional semiconductor layer into the compound semiconductor film.

32. The method of claim 31 wherein the dopant element is selected to be carbon.

33. The method of claim 31 wherein the dopant element is selected to be boron.

34. The method of claim 31 wherein the dopant element is selected to be fluorine.

35. The method of claim 31 wherein the step of controlling the movement of the oxygen is accomplished by controlling a profile of the dopant.

36. The method of claim 31 wherein the step of controlling the movement of the oxygen is accomplished by controlling a temperature of the annealing step.

37. The method of claim 36 wherein the temperature is selected to be about 900° C.

38. The method of claim 31 wherein the step of controlling the movement of the oxygen is accomplished by controlling a time of the annealing step.

39. The method of claim 31 wherein the compound semiconductor film is selected to be silicon germanium.

40. The method of claim 39 wherein the step of controlling the movement of the oxygen is accomplished by controlling a profile of the germanium.

41. The method of claim 39 wherein the step of controlling the movement of the oxygen is accomplished by controlling a percentage of the germanium used in the silicon germanium film.

42. The method of claim 31 wherein the step of controlling the movement of the oxygen is accomplished by controlling a quantity of the oxygen incorporated into the at least one additional semiconductor layer.

43. The method of claim 31 wherein the quantity of oxygen is incorporated by chemical vapor deposition.

44. The method of claim 31 wherein the quantity of oxygen is incorporated by ion implantation.

45. An electronic device comprising:
a substrate;
a silicon germanium film disposed over a first surface of the substrate;
a dopant containing carbon, the dopant incorporated into the silicon germanium film; and
a quantity of oxygen updiffused into the silicon germanium film.

46. An electronic device comprising:
a substrate;
a silicon germanium film disposed over a first surface of the substrate;
a dopant containing boron, the dopant incorporated into the silicon germanium film; and
a quantity of oxygen updiffused into the silicon germanium film.

47. An electronic device comprising:
a substrate;
a silicon germanium film disposed over a first surface of the substrate;
a dopant containing fluorine, the dopant incorporated into the silicon germanium film; and
a quantity of oxygen updiffused into the silicon germanium film.

48. A method for fabricating a heterojunction bipolar transistor, the method comprising:
providing a semiconductor substrate having a first surface;
incorporating a quantity of oxygen into the semiconductor substrate;
forming a silicon germanium film over the first surface of the semiconductor substrate;
doping the silicon germanium film with a strain-compensating atomic species;
annealing the semiconductor substrate and the silicon germanium film; and
controlling movement of the oxygen from the semiconductor substrate into the silicon germanium film.

49. The method of claim 48 wherein the strain-compensating atomic species is selected to be carbon.

50. The method of claim 48 wherein the strain-compensating atomic species is selected to be boron.

51. The method of claim 48 wherein the strain-compensating atomic species is selected to be fluorine.

52. The method of claim 48 wherein the step of controlling the movement of the oxygen is accomplished by controlling a profile of the strain-compensating atomic species.

53. The method of claim 48 wherein the step of controlling the movement of the oxygen is accomplished by controlling a temperature of the annealing step.

54. The method of claim 48 wherein the step of controlling the movement of the oxygen is accomplished by controlling a time of the annealing step.

55. The method of claim 48 wherein the step of controlling the movement of the oxygen is accomplished by controlling a profile of the germanium.

56. The method of claim 48 wherein the step of controlling the movement of the oxygen is accomplished by controlling a quantity of the oxygen incorporated into the semiconductor substrate.

57. The method of claim 48 wherein the semiconductor substrate is selected to be silicon.

58. The method of claim 57 wherein the quantity of oxygen is incorporated by growing a silicon ingot to produce the semiconductor substrate by Czochralski ingot formation.

59. The method of claim 48 wherein the quantity of oxygen is incorporated by chemical vapor deposition.

60. The method of claim 48 wherein the quantity of oxygen is incorporated by ion implantation.

61. A method for fabricating a heterojunciton bipolar transistor, the method comprising:
providing a substrate having a first surface;
forming a silicon germanium film over at least a first portion of the first surface of the substrate;
doping the silicon germanium semiconductor film with a strain-compensating atomic species;
forming at least one additional semiconductor layer adjacent to the silicon germanium film;
incorporating a quantity of oxygen into the at least one additional semiconductor layer;
annealing the substrate, the silicon germanium film, and the at least one additional semiconductor layer; and
controlling movement of the oxygen from the at least one additional semiconductor layer into the silicon germanium film.

62. The method of claim 61 wherein the strain-compensating atomic species is select to be carbon.

63. The method of claim 61 wherein the strain-compensating atomic species is select to be boron.

64. The method of claim 61 wherein the strain-compensating atomic species is select to be fluorine.

65. The method of claim wherein the step of controlling the movement of the oxygen is accomplished by controlling a profile of the strain-compensating atomic species.

66. The method of claim wherein the step of controlling the movement of the oxygen is accomplished by controlling a temperature of the annealing step.

67. The method of claim wherein the step of controlling the movement of the oxygen is accomplished by controlling a time of the annealing step.

68. The method of claim wherein the step of controlling the movement of the oxygen is accomplished by controlling a profile of the germanium.

69. The method of claim wherein the step of controlling the movement of the oxygen is accomplished by controlling a quantity of the oxygen incorporated into the semiconductor substrate.

70. The method of claim 61 wherein the semiconductor substrate is selected to be silicon.

71. The method of claim 70 wherein the quantity of oxygen is incorporated by growing a silicon ingot to produce the semiconductor substrate by Czochralski ingot formation.

72. The method of claim 61 wherein the quantity of oxygen is incorporated by chemical vapor deposition.

73. The method of claim 61 wherein the quantity of oxygen is incorporated by ion implantation.
